(19) United States
(12) Patent Application Publication
(10) Pub. No.: US 2022/0117115 A1
(43) Pub. Date: Apr. 14, 2022

(54) Multi-Material, Variable Heat Flux Cold Plate

(71) Applicant: Jetcool Technologies Inc., Littleton, MA (US)

(72) Inventors: Bernard Malouin, Westford, MA (US); Jordan Mizerak, Boston, MA (US)

(21) Appl. No.: 17/497,919

(22) Filed: Oct. 9, 2021

Related U.S. Application Data
(60) Provisional application No. 63/089,636, filed on Oct. 9, 2020.

(51) Int. Cl. H05K 7/20

(52) U.S. Cl. CPC H05K 7/20254

(57) ABSTRACT

A single-phase liquid-cooled cold plate for thermal management of heat dissipating electronic devices or assemblies. Within the cold plate are non-uniform nozzle arrangements that produce spatially-varying heat transfer to mitigate device hot spots. The cold plate is comprised of thermally-conductive and thermally-insulating materials to enhance heat transfer while suppressing parasitic losses within the cold plate.

### CROSS-REFERENCE TO RELATED APPLICATION

This application claims priority of Provisional Application 63/089,636 filed on Oct. 9, 2020, the entire disclosure of which is incorporated herein by reference, for all purposes.

### BACKGROUND

This disclosure relates to a cold plate.

Electronics in wireless communications, computing, and industrial processes are becoming higher power with more functionality integrated into single devices. In computing, for example, processing and memory are built into single chips or multi-chip assemblies. This path toward higher power and added functionality has led to increasing heat loads on electronic devices. Additionally, the disparate functionality incorporated into single devices or stackups produces nonuniform distribution of the heat. This nonuniform heat generation from these devices produces patterns of localized hot spots; that is, spatially-variable heat fluxes.

Current approaches to cool these types of devices include liquid-cooled cold plates. Cold plates have been constructed as flat plates comprised of a thermally conductive material (typically a metal). A fluid passage, or reservoir, is formed within the plate. Sometimes this passage is in the form of a channel or tube to transport the liquid throughout the plate. These cold plates are attached (via a thermal interface material) to the electronic device. In this way, heat is conducted from the device to the conductive plate where it is spread and transferred into the liquid coolant.

While such approaches are effective at cooling many of today's electronics, they lack the ability to match cooling capacity with local device hot spots—instead opting to spread out the heat. This results in lifetime- and performance-limiting local hot spots on the device. Moreover, because current cold plates are made from thermally-conductive materials to spread the heat, there can be considerable “cross talk” (i.e., heat transfer) between the cold (inlet) coolant and the warm (outlet) coolant. This can cause undesirable heating of the inlet coolant before it is available to remove heat that is from the device(s) being cooled. When the inlet fluid is heated before it is available to remove unwanted heat, the temperature differential between the cold plate and the cooling fluid is reduced, leading to lower heat transfer rates, which reduces the effectiveness of the overall cold plate.

It would, therefore, be useful to have a cold plate that: offers higher cooling for local hot spots; minimizes thermal gradients even with variable heat fluxes; and reduces parasitic losses between cold and hot fluid within the plate to increase overall performance.

### SUMMARY

In one embodiment, a multi-material, variable heat flux cold plate is described to address the challenges in current cold plate approaches. A multi-material, variable heat flux cold plate forms a cooling plate that keeps the cooling fluid sealed within it, except for the inlet and discharge of the coolant fluid through at least one inlet port or fitting and at least one outlet port or fitting. That is, fluid supplied to the multi-material, variable heat flux cold plate serves to provide specialized fluid passages to exploit the heat transfer characteristics of the cooling fluid while restricting the fluid's flow to within the cold plate, except to accept incoming supply fluid and discharge warmed effluent fluid.

Furthermore, within the fluid passages the heat transfer capability of the moving fluid is designed to allow regions of very high heat transfer and those of ordinary heat transfer. For example, arrays of small nozzles may be used to create impinging jets of fluid in certain areas. The distribution of these nozzles may be non-uniform to produce locally high heat transfer coefficients. In such an approach, areas of high heat transfer capacity can be matched to local heat-producing locations on the electronic device. This can eliminate the presence of local hot spots caused by variable heat fluxes in the electronic device. These local hot spots would otherwise limit overall device performance, reliability, and lifetime.

In liquid cooling approaches where cold (supply) and hot (effluent) fluids are used within a cold plate, overall cooling efficiency is decreased as heat is ultimately transferred between the hot effluent and the cold supply before cooling the heat-generating device. This parasitic loss is caused by the conduction of heat between the hot and cold fluids, which may be in close proximity. This conduction occurs because the cold plate is constructed from a thermally-conductive material (e.g., metal), owing from the need to conduct the heat from the heat-generating device to the fluid within.

In one embodiment of the multi-material, variable heat flux cold plate this limitation may be decreased or removed by using a composite construction. That is, pieces of different material composition can be assembled to form a higher performance cold plate.

In one embodiment, a multi-material, variable heat flux cold plate for cooling an electronic component includes one or more fluid passages contained within the cold plate structure, at least one fluid supply inlet port that is fluidly coupled to the internal fluid passage, and at least one fluid discharge outlet port that is fluidly coupled to the internal fluid passage. There is at least one supply reservoir fluidly coupled to the internal fluid passage, at least one heat transfer reservoir fluidly coupled to the internal fluid passage, and regions of varying heat transfer capability within the at least one heat transfer reservoir or internal fluid passage.

In such an embodiment, a heat transfer plate may be comprised of a thermally-conductive material (e.g., metal). This serves to transfer the heat from the heat-generating device to an inner surface of the cold plate that is in communication with the fluid. Other portions of the composite cold plate, which may include the entirety of the remainder of the cold plate, may be comprised of non-thermally-conductive materials or materials with very low thermal conductivity (e.g., insulators such as plastics). In this way, heat transfer to the fluid is restricted to inner surfaces of the heat transfer plate. While this imposes some limitations in the ability to spread heat, it also decreases the parasitic losses between hot and cold fluids otherwise contained within the cold plate. The addition of variable heat flux cooling (i.e., areas of very high heat transfer that are aligned with areas of high device heat-generation) greatly reduce the importance of heat spreading and highlight the importance of minimizing parasitic losses. Of course, this also frees the design space from using thermally-conductive materials in more areas than is ultimately necessary—producing benefits in weight, corrosion resistance, and cost.

All examples and features mentioned below can be combined in any technically possible way.

In one aspect, a cold plate that is configured to be thermally coupled to an electronic component includes a heat transfer structure comprising a thermally-conductive material, and configured to draw heat from the electronic component, wherein the heat transfer structure defines an outer extent of at least part of the cold plate, and has an exterior surface that is configured to be closest to the electronic component, and an opposed internal surface. There is a manifold structure coupled to the heat transfer structure and comprising a material with a lower thermal conductivity than the heat transfer structure, the manifold structure comprising one or more internal fluid passages, at least one fluid supply inlet port that is fluidly coupled to the internal fluid passage, at least one fluid discharge outlet port that is fluidly coupled to the internal fluid passage, and at least one nozzle plate. The at least one nozzle plate defines a series of orifices that are configured to provide fluid jets that issue onto the internal surface of the heat transfer structure.

Some examples include one of the above and/or below features, or any combination thereof. In an example at least one nozzle plate is part of the manifold structure. In an example the manifold structure is made entirely from a thermally-insulating material. In an example the thermally-insulating material is a plastic. In an example the orifices are non-uniformly configured. In an example the orifices are non-uniformly distributed across the at least one nozzle plate. In an example the orifices are non-uniform in size.

Some examples include one of the above and/or below features, or any combination thereof. In an example the orifices are arranged in a regular pattern. In an example the orifices contain geometric features for enhanced fluid flow. In an example the geometric features consist of chamfered or streamlined edges that serve to reduce pressure drop through the orifices. In an example a single-phase liquid is disposed within the cold plate and remains a single-phase liquid while contained within the cold plate. In an example the construction of the cold plate is comprised of at least one thermally-conductive material and at least one thermally-insulating material. In an example the heat transfer structure is comprised of a thermally-conductive material and at least the nozzle plate is comprised of thermally-insulating material. In an example the manifold structure that separates the internal fluid passages comprises a thermally-insulating material. In an example the internal surface of the heat transfer structure has disposed on it features for area-enhancement or flow control. In an example the features are vertically aligned with the location of orifices within the nozzle plate. In an example the features are located away from the vertical alignment axes of orifices within the nozzle plate.

In another aspect a cold plate for cooling an electronic component with a non-uniform spatial heat flux includes one or more internal fluid passages, at least one fluid supply inlet port that is fluidly coupled to an internal fluid passage, at least one fluid discharge outlet port that is fluidly coupled to an internal fluid passage, at least one internal supply reservoir that is fluidly coupled to an internal fluid passage, at least one internal heat transfer reservoir that is fluidly coupled to an internal fluid passage and at least one nozzle plate that separates the at least one internal supply reservoir and the at least one internal heat transfer reservoir. The at least one nozzle plate defines a series of orifices that are configured to provide fluid jets that issue from the supply reservoirs into the heat transfer reservoirs, wherein the fluid jets are configured to accomplish non-uniform heat transfer that accommodates the non-uniform spatial heat flux of the electronic component.

Some examples include one of the above and/or below features, or any combination thereof. In an example the at least one nozzle plate is made entirely from a thermally-insulating material. In an example the thermally-insulating material is a plastic. In an example the orifices are non-uniformly configured. In an example the orifices are non-uniformly distributed across the at least one nozzle plate. In an example the orifices are non-uniform in size.

In another aspect a cold plate for cooling an electronic component with a non-uniform spatial heat flux includes a heat transfer structure comprising a thermally-conductive material, and configured to draw heat from the electronic component, wherein the heat transfer structure defines an outer extent of at least part of the cold plate, and has an exterior surface that is configured to be closest to the electronic component and an opposed internal surface. There is at least one nozzle plate that defines a series of orifices that are configured to provide fluid jets that issue onto the internal surface of the heat transfer structure.

Some examples include one of the above and/or below features, or any combination thereof In an example the at least one nozzle plate is made entirely from a thermally-insulating material. In an example the thermally-insulating material is a plastic. In an example the orifices are non-uniformly configured. In an example the orifices are non-uniformly distributed across the at least one nozzle plate. In an example the orifices are non-uniform in size.

### BRIEF DESCRIPTION OF THE DRAWINGS

Various aspects of at least one example are discussed below with reference to the accompanying figures, which are not intended to be drawn to scale. The figures are included to provide illustration and a further understanding of the various aspects and examples, and are incorporated in and constitute a part of this specification, but are not intended as a definition of the limits of the inventions. In the figures, identical or nearly identical components illustrated in various figures may be represented by a like reference character or numeral. For purposes of clarity, not every component may be labeled in every figure. For a better understanding of the present disclosure, reference is made to the accompanying drawings, in which:

FIG. 1 is a conceptual schematic for a component or assembly on a cold plate.

FIG. 2 is a top view of a heat-generating device (e.g., a computer processor) with constant temperature lines, indicating the presence of local hot spots due to non-uniform heat generation within the electronic device.

FIG. 3 is a cross sectional view of a prior art conductive cold plate with internal fluid passages that provide cooling, designed to cool a component or a printed circuit board assembly.

FIG. 4 is a cross section of one embodiment of a multi-material, variable heat flux cold plate with an internal reservoir that supplies coolant fluid to an array of nozzles where the nozzles are non-uniform in distribution to provide variable heat transfer capability to the heat-generating component, reducing the presence of hot spots.

FIG. 5 is a cross sectional view of one embodiment of a multi-material, variable heat flux cold plate comprised of at least two pieces of materially different composition. The heat transfer plate serves to conduct heat while the remainder of the structure is thermally non-conductive to inhibit parasitic losses between hot and cold fluids in close proximity within the cold plate.

FIG. 6 illustrates aspects of an embodiment of a multi-material, variable heat flux cold plate where the one or more internal nozzles include a pressure-reducing inlet feature to reduce the pressure drop of the cold plate.

FIG. 7 is a top cross-sectional view of a multi-material, variable heat flux cold plate where different regions in the cold plate have intentionally different heat transfer capability to minimize hot spots and thermal gradients across or between heat-generating components.

### DETAILED DESCRIPTION

Examples of the systems, methods and apparatuses discussed herein are not limited in application to the details of construction and the arrangement of components set forth in the following description or illustrated in the accompanying drawings. The systems, methods and apparatuses are capable of implementation in other examples and of being practiced or of being carried out in various ways. Examples of specific implementations are provided herein for illustrative purposes only and are not intended to be limiting. In particular, functions, components, elements, and features discussed in connection with any one or more examples are not intended to be excluded from a similar role in any other examples.

Examples disclosed herein may be combined with other examples in any manner consistent with at least one of the principles disclosed herein, and references to “an example,” “some examples,” “an alternate example,” “various examples,” “one example” or the like are not necessarily mutually exclusive and are intended to indicate that a particular feature, structure, or characteristic described may be included in at least one example. The appearances of such terms herein are not necessarily all referring to the same example.

Also, the phraseology and terminology used herein is for the purpose of description and should not be regarded as limiting. Any references to examples, components, elements, acts, or functions of the computer program products, systems and methods herein referred to in the singular may also embrace embodiments including a plurality, and any references in plural to any example, component, element, act, or function herein may also embrace examples including only a singularity. Accordingly, references in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

Some examples of this disclosure describe the use of a cold plate that produces increased heat transfer performance by allowing a coolant fluid to pass through internal, non-uniform arrangements of nozzles that accelerate flow toward an internal heat transfer surface. This non-uniform arrangement provides tailored heat transfer characteristics that mitigate the deleterious effects of spatially-variable heat flux within the heat-generating device. This may eliminate device hot spots and thermal gradients, while doing so more efficiently by increasing cooling only in the areas that need it. The disclosure further describes several beneficial features of this multi-material, variable heat flux cold plate, including the ability to increase overall effectiveness by minimizing the parasitic losses typically associated with heat transfer between the hot and cold fluids within the plate. This parasitic heat transfer (or “cross talk”) would otherwise warm the incoming cool fluid, thereby reducing its effectiveness when finally needed to cool the heat-generating device. One embodiment accomplishes this by implementing multiple pieces of disparate material construction—one thermally-conductive heat transfer plate and one or more non-thermally conductive structures and nozzle plates. Such an approach has other benefits, as well, including lower weight and cost.

The disclosure further describes several possible embodiments of the multi-material, variable heat flux cold plate, including internal geometry architectures and features to achieve high performance, and some examples of multi-material, variable heat flux cold plate assemblies. This disclosure adds new features (variable heat flux cooling, pressure reducing nozzle entries, insulating flow walls) to a common thermal management approach (cold plates) in order to achieve higher performance and relax material constraints.

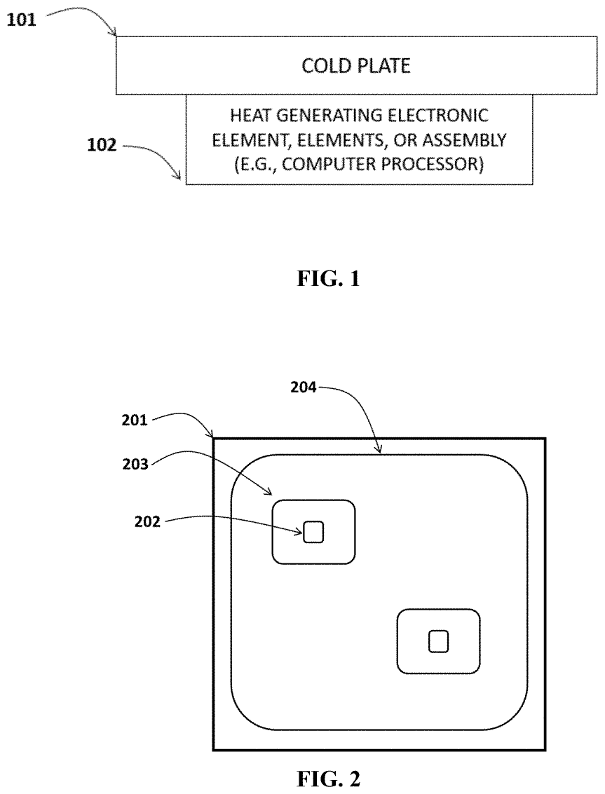

Many system level assemblies are comprised of multiple components, including many electrical components and/or printed circuit boards (PCBs). These system level assemblies often include thermal management hardware, such as fans, heat spreaders, or cold plates. Such an arrangement is shown in FIG. 1, where one or more heat generating elements or assemblies (102) are disposed on a cold plate (101). The heat generating elements or assemblies may be, for example, packaged, lidded, or bare die devices. In some instances, for example computer processors, the liquid-cooled cold plate (101) may be disposed on the computer processor (e.g., 102), which may be mounted to another assembly, like a PCB (not shown).

While many electronic devices produce nearly uniform heat distribution (heat flux), some devices generate highly non-uniform heat distributions. This is often seen in advanced semiconductors which may, for example: have heating concentrated along device edges; build devices from 3D integrated or stacked dies with different or non-uniform height; or create subassemblies from multiple dies (multi-chip modules) of different power. Such spatially-varying heat fluxes are often manifested through localized hot spots imprinting on the device. A computer processor is one such example of a heat-generating device that can exhibit highly non-uniform heat fluxes. This is illustrated in FIG. 2, where a computer processor (201) is depicted. Due to the specific processor's architecture, local regions may dissipate more heat than others. This is visualized by examining contours of constant temperature (202-204) on the device. The variable heat flux across the device surface produces local “hot spots”. In one example contour of highest temperature (202) covers a very small area within the device due to the area of localized high heat flux. An intermediate temperature contour (203) covers a larger area than the highest temperature contour, but still highly localized compared to the overall device footprint. Finally, low temperature contour (204) may not have any appreciable temperature difference from the ambient environment due to the concentrated heat loads, or else is often significantly lower in temperature compared to high temperature contour (202). Manufacturers must characterize the device reliability and lifetime based on maximum temperature seen in the device, at or above the highest temperature contour (202) depending on the device stackup. Therefore, these local hot spots can produce a significant impact on device specifications. However, eliminating these small, high power-density hot spots is very challenging.

In the case of cold plates, a coolant fluid is circulated within a thermally conductive structure. Heat-dissipating components and/or assemblies are then attached to the outer surface of the structure (i.e., the cold plate), typically by a thermal interface material (TIM). This TIM is commonly an elastomeric pad, thermal epoxy, or a thermal paste. The TIM fills in the small area between the component surface and the cold plate surface, which is an area that would otherwise be occupied by very low conductivity air. In this way, heat that is generated from the component is conducted to the component's outer surface, then through the TIM, then through the conductive surface of the cold plate, and ultimately transferred into the coolant fluid buried within the cold plate.

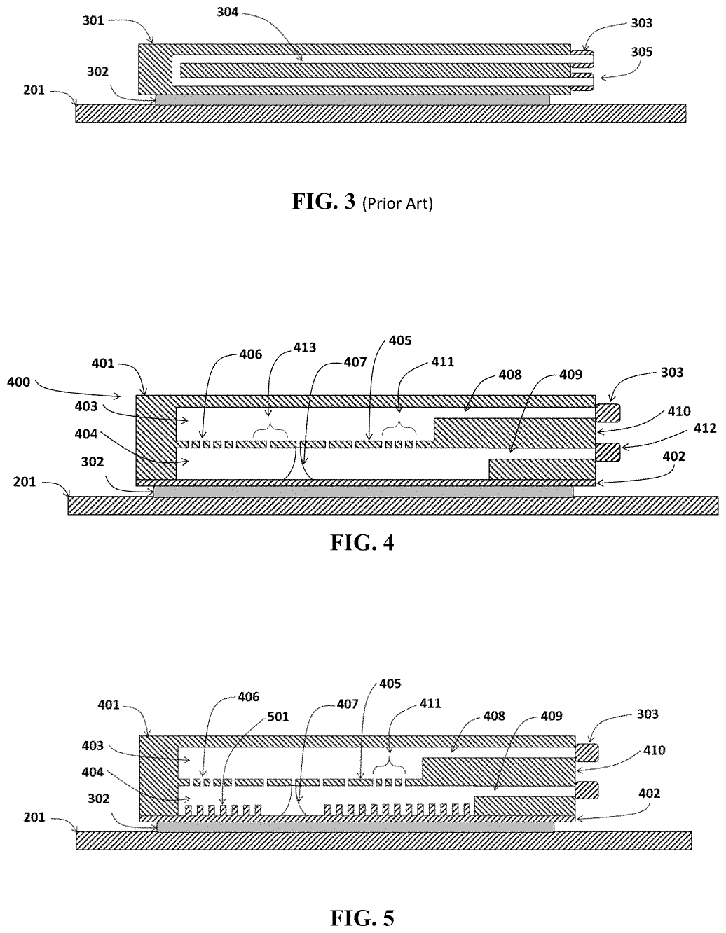

FIG. 3 illustrates such a prior art cold plate assembly. A thermally conductive cold plate (301) (e.g., entirely made of a heat-conductive metal such as copper) has contained within it one or more fluid passages (304). Coolant fluid flows through these passages, from an inlet (303) to an outlet (305), cooling the cold plate (301). In many instances, a computer processor (201) is disposed onto the cold plate. When the computer processor is attached to the cold plate, contact is made between the processor (201) and the cold plate (301) surface by a layer of TIM (302).

In this architecture, the heat dissipated by the heat-generating component (201) is conducted through the TIM layer (302) and then into the thermally-conductive cold plate (301). Within the thermally-conductive cold plate, the heat spreads until it is coupled into the cooling fluid within the one or more internal fluid passages (304).

The above approach is effective for transferring the heat from components with moderate heat fluxes, or those robust against the deleterious effects of temperature gradients (e.g., reduced lifetimes, stress buildup, resistive changes, etc.). However, for components with highly variable surface heat fluxes and temperature-dependent characteristics, the inability of prior art cold plates to preferentially target and eliminate the resulting hot spots is significant. Moreover, even for low power components, the traditional cold plate design requires the entire cold plate to be thermally conductive, which leads to heat being exchanged in the cold plate between the cold supply fluid and the hot effluent fluid in a phenomenon known as parasitic cross talk. This parasitic loss reduces the overall efficiency of the cold plate as the desired heat transfer surface is no longer cooled by the coldest possible coolant.

This disclosure describes a multi-material, variable heat flux cold plate for electronics cooling. The multi-material, variable heat flux cold plate is comprised of one or more internal arrays of fluid nozzles, of non-uniform distribution (in spacing, diameter, or other characteristic), to create tailored regions of heat transfer capability. The heat transfer capability (expressed as W/cm\hat{ }2, for example) of different regions may, for example, differ by a factor of ten or more. These areas of different heat flux or heat transfer capability are approximately aligned with the matching heat fluxes of the device to reduce or minimize the presence of device hot spots, with or without spreading within the cold plate.

FIG. 4 illustrates one embodiment of a multi-material, variable heat flux cold plate. The cold plate 400 (comprised of separate parts or portion 401 and 402 that are coupled/fixed together) has disposed within it fluid passages (408, 409) that guide coolant fluid from an inlet (303) to an outlet (412). In this embodiment, a computer processor (201) is disposed on the cold plate with a TIM (302). The multi-material, variable heat flux cold plate is comprised of at least two pieces, a manifold structure (401) and a heat transfer plate (402). Much or all of the fluid routing may occur in the manifold structure, while the heat transfer occurs at the heat transfer plate. In one embodiment, these pieces are made from different materials, for example where the heat transfer plate is constructed from thermally-conductive material (e.g., metal, ceramics, graphite) and where the manifold is constructed from non-thermally-conductive material or a material with lower thermal conductivity than the heat transfer plate (e.g., plastic, resin, elastomers, low conductivity metals, semiconductors, etc.).

The fluid passages (408, 409) deliver fluid to a supply reservoir (403) that is contained within the multi-material, variable heat flux cold plate. At least one boundary of the supply reservoir (403) is formed by a nozzle plate (405). Disposed within this nozzle plate (405) are a plurality of nozzles (406).

Flow is created as coolant fluid from an inlet (303) is directed through internal fluid passages (408), filling an internal supply reservoir (403). The multi-material, variable heat flux cold plate has disposed within it a nozzle plate (405) with one or more orifices or nozzles (406). The orifices on the nozzle plate may be, for example, circular in cross section with a diameter in the range of 100 μm to 750 μm. Other shapes and diameters are, of course, possible. This nozzle plate (405) takes the coolant fluid and forms it into one or more fluid jets (407). The fluid jet may exit at velocities of, for example, 3 m/s to 27 m/s. Other velocities are, of course, possible.

Such microjet cooling is a technique for cooling high-power devices that is characterized by fluid moving through a nozzle to form a small jet of fluid with substantially greater momentum in one direction than another. When this high-momentum fluid impacts a surface, it minimizes the thermal boundary layer at that surface, producing very high heat transfer at that spot. Arrays of microjets can then expand the overall spot size of high heat transfer. Microjet cooling technology has been demonstrated to produce heat transfer coefficients in excess of 200,000 W/m²K, more than 10 times that of competing approaches (e.g., microchannels≈20,000 W/m²K). This allows the fluid to collect more heat, without the need for additional metal heat spreaders. Importantly, the multi-material, variable heat flux cold plate has disposed within it a single-phase liquid coolant. By remaining single-phase and liquid, very high heat transfer coefficients can be achieved without the need for additional infrastructure or design elements to separate the liquid and vapor constituents. Additionally, the jets are surrounded by the same liquid phase, creating a neutrally buoyant system that is gravitationally insensitive. This is not the case for two-phase systems.

The fluid jet or jets (407) issue into the heat transfer reservoir (404) and strike the inner surface(s) of the heat transfer plate (402). Heat is effectively transferred from the device, through the heat transfer plate (which may be much thinner, for example 0.1 mm to 1.2 mm as spreading is not required), and to the fluid. After striking the heat transfer plate, the jet fluid then occupies the heat transfer reservoir until the fluid enters another internal fluid passage (409).

Importantly, it has been described that heat-generating device (201) may have a non-uniform heat flux which produces hot spots. The multi-material, variable heat flux cold plate can mitigate these localized hot spots with corresponding non-uniform arrays of nozzles and fluid jets, which create non-uniform heat transfer capabilities across the surface area of heat transfer plate (402). When microjets are arranged to impact the underside/inside surface of heat transfer plate (402) in locations of higher heat flux, localized hot spots are reduced, which mitigates the deleterious effects of thermal gradients within the device or assembly. For example, a nozzle plate (405) may have regions of more densely packed nozzles (411) and areas of more sparse nozzles (413) to cool high and moderate heat flux regions, respectively. Of course, packing density is only one variable that may be non-uniform and others are possible. Such non-uniform arrangements of nozzles allow for tailoring of the level of cooling within the multi-material, variable heat flux cold plate to match the heat flux of the heat-generating device and eliminate hot spots and thermal gradients. That is, the non-uniformity in nozzle arrangement produces greater uniformity in device temperature.

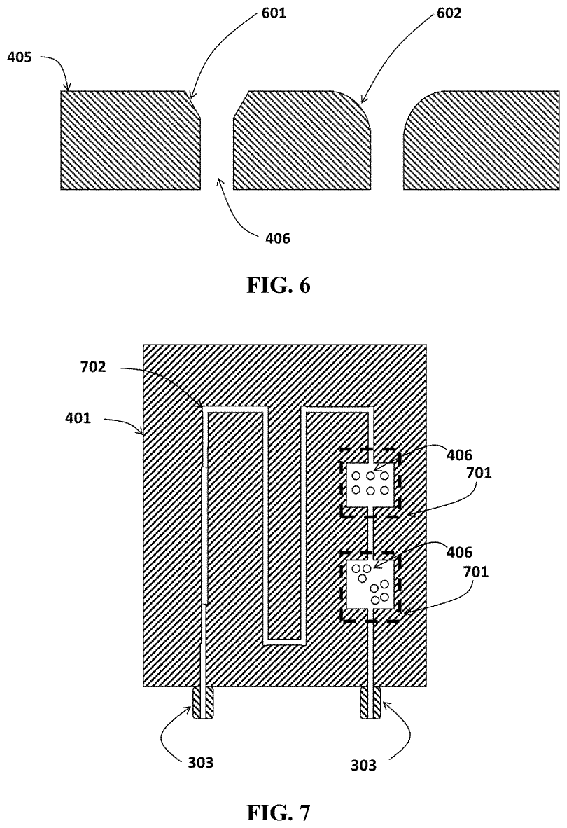

Other features may also be disposed on the inner surface of the heat transfer plate (402). In some examples these features increase the heat-transfer rate of the heat transfer plate (402) in the area of these features. For example, FIG. 5 illustrates one embodiment where features (501) are disposed on the inner surface of the heat transfer plate (402). In one example, these features (501) may be area-enhancing circular cross section pins. As the heat transfer rate into a flowing coolant is proportional to the total heated area it is in contact with, having area-enhancing pins may result in an increase in heat transfer, thereby allowing for higher total power devices or devices with higher heat fluxes. . Alternatively, the area enhancement of these features may be used to reduce the surface-liquid superheat and therefore suppress boiling; that is, the features may act as “anti-boiling” features to preserve the single-phase nature of this disclosure. In other examples they may, for example, also function as flow-controlling features and/or flow turbulators in the heat transfer reservoir and be disposed vertically-aligned with the jets or intentionally located away from the jets. Of course, other implementations of features (501) are also possible including slots, channels, prisms, or surface roughness. These features act similarly to circular cross section pins, but depending on the implementation may have other potential benefits such as, for example, optimized pressure drops, ease of manufacturing, nucleation suppression, boundary layer management, fouling mitigation, or flow path curation.

A pressurized fluid is needed to drive the flow within the multi-material, variable heat flux cold plate. To be most practicable, however, it may be advantageous to minimize the pressure needed to drive the fluid. Pressure-reducing features may be included in the multi-material, variable heat flux cold plate, for example at the nozzle inlet. FIG. 6 illustrates two embodiments of pressure reducing nozzle inlet features. Within the nozzle plate (405) may be disposed one or more nozzles (406). The nozzle inlet may be shaped in such a way to reduce the pressure needed to drive the flow through the nozzle. In the example of FIG. 6, two different pressure reducing nozzle inlet features are illustrated, a chamfered nozzle inlet feature (601) and a streamlined nozzle inlet feature (602). Note that the geometric features of the chamfer or streamline such as angle, depth, and diameter are chosen to produce an optimal desired result. Of course, other geometric variations may be possible.

The non-uniform nozzles forming fluid jets contained within the interior of the multi-material, variable heat flux cold plate can eliminate device hot spots. The effectiveness of the microjet cooling within the plate also eliminates the need for spreading heat within the cold plate itself. In fact, the multi-material, variable heat flux cold plate may be specifically constructed from different materials to inhibit the spreading and transfer of heat within the manifold structure (401) to increase overall efficiency.

In current cold plate approaches, the cold plate (301) must be constructed from a thermally-conductive material in order to successfully transfer the heat from the (external) heat-generating device, through the cold plate structure, and into the fluid. While some heat spreading within the cold plate can be helpful for thermal performance, the true benefit is often lessened by parasitic heat loss between the cold supply fluid and the hot effluent fluid.

For example, cold supply fluid may be present in the supply passage (408) of FIG. 5. After picking up heat from the device, hot effluent fluid may be present in the discharge passage (409). These two passages may be in close proximity to one another, separated only by a small section of the cold plate (410). By laws of physics, heat is conducted from the hot fluid (409), through the cold plate (410), and into the cold fluid (408). This “thermal cross talk” warms the supply fluid before it has a chance to cool the device. This reduces overall efficiency as the device no longer sees the coolest possible fluid. A thermally conductive section (410) exacerbates this problem.

In contrast, one embodiment of the multi-material, variable heat flux cold plate is constructed from at least two materials: one thermally-conductive and one thermally insulating. The heat transfer plate (402) is constructed from thermally-conductive materials. The manifold (401), including the thermal cross-talk section (410) may be made from thermally-insulating materials. This architecture preserves the microjet heat transfer at the heat transfer plate while minimizing the parasitic losses within the remainder of the multi-material, variable heat flux cold plate. Thermally-conductive materials may include copper, aluminum, silicon carbide, or other materials. Thermally-insulating materials may include plastics, resins, foams, air gaps, partial vacuum, other materials, or combinations of these.

In the embodiment shown in FIG. 5, the multiple materials are joined to form a leak-tight seal between the manifold (401) and the heat transfer plate (402). Such assembly may be accomplished through a variety of processes. Such approaches may include fasteners, gaskets, O-rings, friction stir welding, brazing, adhesives, laser welding, or other processes. Of course, a single-piece manifold (401) is meant as one possible embodiment; it may be one or several pieces. A completely unitary (i.e., single piece) structure is also possible, such as, for example, a cold plate made from additive manufacturing technologies leveraging multi-material composite joining techniques.

Of course, the use of non-uniform nozzles need not form the entirety of a multi-material, variable heat flux cold plate. The variable heat flux capability may be limited to certain portions of the plate to still produce a certain effect. That is, the multi-material, variable heat flux cold plate may have more than one device or component disposed on it. One or more of the devices or components may have non-uniform heat generation and benefit from the features and methods of this disclosure. As an example, FIG. 7 depicts a top cross-sectional view of one possible embodiment of a multi-material, variable heat flux cold plate (401) where only two zones (701) include nozzles (406) for the non-uniform cooling. Other areas of the cold plate, such as internal flow sections (702), may rely only on standard liquid cold plate approaches, such as where heat is removed via flow through a macro level channel. In this case, flow through internal flow sections (702) would not match the level of cooling performance as the localized cooling zones (701) but would still benefit from the efficiency gains of reduced thermal crosstalk via construction of disparate materials.

Variations of the assembly are also possible. For example, the non-uniform nozzle array may be non-uniform within a given array or may have separate sections of uniform patterns that, together, are non-uniform in arrangement. In the latter, individual sections within an overall cold plate nozzle arrangement may be linear arrays, radial arrays, or any other pattern that serves to help cover the inner surface of the heat transfer plate. The microjets formed from the nozzle plate may also be oriented to strike perpendicularly to the heat transfer plate inner surface or may be given some nominal angle off perpendicular. Moreover, the heat transfer plate inner surface, while shown as flat and smooth, is not limited to such and may include angled sections, roughness, or other features.

In such embodiments containing nozzles or nozzle plates, the nozzles may be disposed in arrays so as to provide cooling for electronic devices of a range of different sizes. Such devices may contain length scales that range from 5-90 mm, for example. Also, there may be more than one device disposed on a single multi-material, variable heat flux cold plate.

As part of this disclosure, fluid-cooled cold plates (as used with many electronic devices) are constructed where the single-phase liquid coolant is passed within the interior of the plate and through non-uniform nozzle plates to produce non-uniform cooling capacity. This non-uniform cooling is tailored to match the spatial heat flux variation of the device to be cooled. This reduces the presence of local hot spots within the device. Moreover, by targeting individual hot spots, spreading of heat throughout the entire cold plate is no longer necessary. This allows the use of multiple materials in the construction including thermally-conductive and thermally-insulating materials. By decoupling the need for thermally-conductive materials in only a portion of the plate, parasitic losses in the plate interior can be reduced, producing a higher effectiveness, lighter, more cost effective solution. These multi-material, variable heat flux cold plates are designed to take the place of commonly available metal cold plates in applications where heat is generated non-uniformly by the device or assembly.

The present disclosure is not to be limited in scope by the specific embodiments described herein. Indeed, other various embodiments of and modifications to the present disclosure, in addition to those described herein, will be apparent to those or ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A cold plate that is configured to be thermally coupled to an electronic component, comprising:
a heat transfer structure comprising a thermally-conductive material, and configured to draw heat from the electronic component, wherein the heat transfer structure defines an outer extent of at least part of the cold plate, and has an exterior surface that is configured to be closest to the electronic component, and an opposed internal surface;
a manifold structure coupled to the heat transfer structure and comprising a material with a lower thermal conductivity than the heat transfer structure, the manifold structure comprising one or more internal fluid passages, at least one fluid supply inlet port that is fluidly coupled to the internal fluid passage, and at least one fluid discharge outlet port that is fluidly coupled to the internal fluid passage; and
at least one nozzle plate, wherein the at least one nozzle plate defines a series of orifices that are configured to provide fluid jets that issue onto the internal surface of the heat transfer structure.

2. The cold plate of claim 1, wherein the at least one nozzle plate is part of the manifold structure.

3. The cold plate of claim 2, wherein the manifold structure is made entirely from a thermally-insulating material.

4. The cold plate of claim 3, wherein the thermally-insulating material is a plastic.

5. The cold plate of claim 1, wherein the orifices are non-uniformly configured.

6. The cold plate of claim 5, wherein the orifices are non-uniformly distributed across the at least one nozzle plate.

7. The cold plate of claim 5, wherein the orifices are non-uniform in size.

8. The cold plate of claim 1, wherein the orifices are arranged in a regular pattern.

9. The cold plate of claim 1, wherein the orifices contain geometric features for enhanced fluid flow.

10. The cold plate of claim 9, wherein the geometric features consist of chamfered or streamlined edges that serve to reduce pressure drop through the orifices.

11. The cold plate of claim 1, wherein a single-phase liquid is disposed within the cold plate and remains a single-phase liquid while contained within the cold plate.

12. The cold plate of claim 1, wherein the construction of the cold plate is comprised of at least one thermally-conductive material and at least one thermally-insulating material.

13. The cold plate of claim 12, wherein the heat transfer structure is comprised of a thermally-conductive material and at least the nozzle plate is comprised of thermally-insulating material.

14. The cold plate of claim 12, wherein the manifold structure that separates the internal fluid passages comprises a thermally-insulating material.

15. The cold plate of claim 12, wherein the internal surface of the heat transfer structure has disposed on it features for area-enhancement or flow control.

16. The cold plate of claim 15, wherein the features are vertically aligned with the location of orifices within the nozzle plate.

17. The cold plate of claim 15, wherein the features are located away from the vertical alignment axes of orifices within the nozzle plate.

18. A cold plate for cooling an electronic component with a non-uniform spatial heat flux, comprising:
one or more internal fluid passages;
at least one fluid supply inlet port that is fluidly coupled to an internal fluid passage;
at least one fluid discharge outlet port that is fluidly coupled to an internal fluid passage;
at least one internal supply reservoir that is fluidly coupled to an internal fluid passage;
at least one internal heat transfer reservoir that is fluidly coupled to an internal fluid passage; and
at least one nozzle plate that separates the at least one internal supply reservoir and the at least one internal heat transfer reservoir, wherein the at least one nozzle plate defines a series of orifices that are configured to provide fluid jets that issue from the supply reservoirs into the heat transfer reservoirs, wherein the fluid jets are configured to accomplish non-uniform heat transfer that accommodates the non-uniform spatial heat flux of the electronic component.

19. The cold plate of claim 18, wherein the at least one nozzle plate is made entirely from a thermally-insulating material.

20. The cold plate of claim 19, wherein the thermally-insulating material is a plastic.

21. The cold plate of claim 18, wherein the orifices are non-uniformly configured.

22. The cold plate of claim 21, wherein the orifices are non-uniformly distributed across the at least one nozzle plate.

23. The cold plate of claim 21, wherein the orifices are non-uniform in size.

24. A cold plate for cooling an electronic component with a non-uniform spatial heat flux, comprising:
a heat transfer structure comprising a thermally-conductive material, and configured to draw heat from the electronic component, wherein the heat transfer structure defines an outer extent of at least part of the cold plate, and has an exterior surface that is configured to be closest to the electronic component, and an opposed internal surface; and
at least one nozzle plate that defines a series of orifices that are configured to provide fluid jets that issue onto the internal surface of the heat transfer structure.

25. The cold plate of claim 24, wherein the at least one nozzle plate is made entirely from a thermally-insulating material.

26. The cold plate of claim 25, wherein the thermally-insulating material is a plastic.

27. The cold plate of claim 24, wherein the orifices are non-uniformly configured.

28. The cold plate of claim 27, wherein the orifices are non-uniformly distributed across the at least one nozzle plate.

29. The cold plate of claim 27, wherein the orifices are non-uniform in size.
